(19) United States
(12) Patent Application Publication
(10) Pub. No.: US 2008/0303533 A1
(43) Pub. Date: Dec. 11, 2008

(54) Cable testing device and testing method thereof

(76) Inventors: Chih-Cheng Wu, Tu-Cheng City (TW); Chin-Chiang Li, Tu-Cheng City (TW); Yu-Hua Hsieh, Tu-Cheng City (TW); Hsing-Hua Hsieh, Tu-Cheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/808,143

(22) Filed: Jun. 7, 2007

(51) Int. Cl. G01R 27/28

(52) U.S. Cl. 324/627

(57) ABSTRACT

A cable testing device of the present invention can test sheltering performance of a cable which has a central wire, a shelter wrapped around the central wire and an exterior cover wrapped around the shelter. One end of the central wire and two ends of the shelter are earthed. The cable testing device includes a network testing device and a metal tube. The network testing device has an input which is connected to the other end of the cable and an output. The metal tube incloses the cable to be tested, one end of the metal tube is connected to the output of the network testing device, the other end is earthed. As a result, an electromagnetic field is formed in the interior of metal tube, thereby, the sheltering performance of the shelter of the cable can be tested directly before the whole cable product being assembled.

### BACKGROUND OF THE INVENTION

1. Field of the Invention

The present invention relates to a cable testing device and testing method thereof, and more particularly to a cable testing device and testing method thereof for testing sheltering performance of the inner shelter of a cable.

2. The Related Art

In modern living environment, electromagnetic wave interference exists everywhere and spoils electronic devices, so the sheltering performance of the electronic device must be tested after the electronic device being made. However, for a long period, the resistance of the interference of the cable product is tested only after the whole product being assembled.

If the sheltering performance of the inner shelter of a cable is tested before the whole product being assembled, the quality of the cable is obtained, and it provides a reference to the design of the cable for improving the sheltering performance of the cable, as a result, a testing device which can directly test the sheltering result of the cable is required.

### SUMMARY OF THE INVENTION

Accordingly, an object of the present invention is to provide a cable testing device and testing method thereof which can directly test the sheltering result of the cable before the cable product being assembled. The cable testing device of the present invention can test sheltering performance of a cable, the cable testing device comprises a network testing device and a metal tube. The network testing device has an input and an output. The metal tube incloses the cable to be tested, one end of the metal tube is connected to the output of the network testing device, the other end is earthed. Both ends of a shelter and one end of a central wire contained in the cable are earthed, and an opposite end of the central wire connects the input of the network testing device for performing cable testing.

The cable testing method of the present invention is provided to test sheltering performance of a cable, the cable has a central wire, a shelter wrapped around the central wire and an exterior cover wrapped around the shelter, the method comprises the steps of: firstly, the cable to be tested is placed in the metal tube, one end of the metal tube is connected with an output of a network testing device, the other end of the metal tube is earthed; secondly, one end of a central wire of the cable is earthed, meanwhile, the two ends of the shelter are also earthed, the other end of the central wire of the cable is connected to the input of the network testing device; next, the output of the network testing device transmits signals to change the charges on the surface of the metal tube, as a result, an electromagnetic field is formed in the interior of the metal tube; then, the input of the network testing device receives electromagnetic induction signals inducted by the central wire of the cable; lastly, the network testing device analyzes the electromagnetic induction signal inducted by the central wire placed in the metal tube, then decides the sheltering performance of the shelter of the cable.

As described above, the electromagnetic field is formed in the interior of the metal tube, thereby, the sheltering performance of the shelter of the cable can be tested directly, as a result, whether the sheltering performance is good or not can be obtained before the whole cable product being assembled, it provides a reference to the design of the cable for improving the sheltering performance of the cable.

### BRIEF DESCRIPTION OF THE DRAWINGS

The present invention will be apparent to those skilled in the art by reading the following description of a preferred embodiment thereof, with reference to the attached drawings, in which:

FIG. 1 is an assembling diagram of a cable testing device of the present invention; and

FIG. 2 is a cross-sectional view of a metal tube and a cable which is placed in the metal tube.

### DETAILED DESCRIPTION OF THE PREFERRED EMBODIMENT

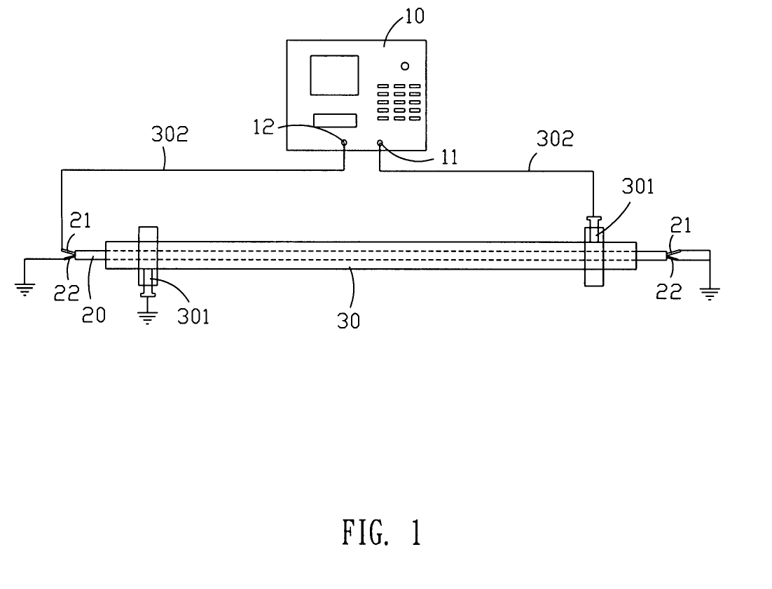

Please refer to FIG. 1, a cable testing device of the present invention includes a signal receiver and an electromagnetic transmitter. In this embodiment, the signal receiver is a network testing device 10 having an output 11 and an input 12, the electromagnetic transmitter is a metal tube 30. A connecting terminal 301 is arranged at each of the two ends of the metal tube 30. One connecting terminal 301 is connected with the output 11 of the network testing device 10 by a testing cable 302, the other connecting terminal 301 is earthed. A circuit is formed between the network testing device 10 and the earth through the output 11 and the metal tube 30, the signals transmitted from the output 11 change the charges on the surface of the metal tube 30, as a result, an electromagnetic field is formed in the interior of the metal tube 30, a testing environment is formed therein.

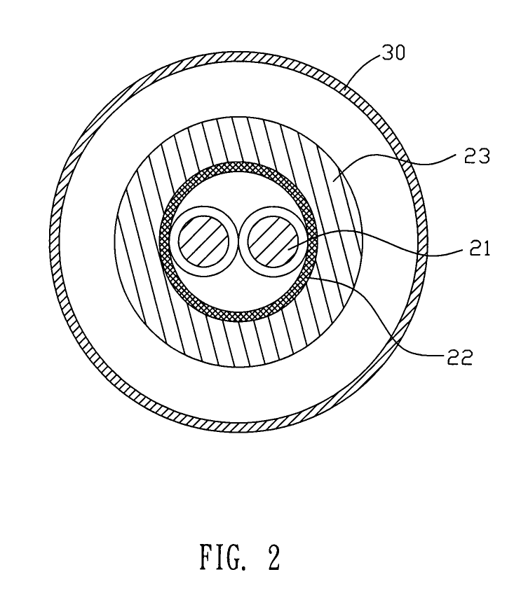

Please refer to FIG. 1 in combination with FIG. 2. In the present invention, the cable 20 which is to be tested is placed in the metal tube 30, the cable 20 includes a central wire 21, a shelter 22 wrapped around the central wire 21 and an exterior cover 23 wrapped around the shelter 22. The cable 20 is moderately longer than the metal tube 30 for exposing the two ends outside the metal tube 30, one end of the central wire 21 is connected with the input 12 of the network testing device 10 by another testing cable 302, the other end of the central wire 21 is earthed, meanwhile, the two ends of the shelter 22 are also earthed to form a receiving portion.

Referring to FIG. 1 again, the testing method of the present invention is described hereinafter.

Firstly, the cable 20 which is to be tested is placed in the metal tube 30, the connecting terminal 301 at one end of the metal tube 30 is connected with the output 11 of the network testing device 10, the connecting terminal 301 at the other end of the metal tube 30 is earthed.

Secondly, one end of the central wire 21 of the cable 20 is connected with the input 12 of the network testing device 10 by another testing cable 302, the central wire 21 at the other end of the cable 20 is earthed, meanwhile, the two ends of the shelter 22 are also earthed.

Next, the output 11 of the network testing device 10 transmits signals to change the charges on the surface of the metal tube 30, as a result, an electromagnetic field is formed in the interior of the metal tube 30.

Then, the input 12 of the network testing device 10 receives electromagnetic induction signals inducted by the central wire 21 of the cable 20.

Lastly, the network testing device 10 records the data and analyzes the electromagnetic induction signal inducted by the central wire 21 placed in the metal tube 30, then decides the sheltering performance of the shelter 22 of the cable 20.

As described above, the electromagnetic field is formed in the metal tube 30, thereby, the sheltering performance of the shelter 22 of the cable 20 can be tested directly, as a result, whether the sheltering performance is good or not can be obtained before the whole cable product being assembled, it provides a reference to the design of the cable for improving the sheltering performance of the cable.

What is claimed is:

1. A cable testing device for testing sheltering performance of a cable, comprising:
a network testing device, having an input and an output; and
a metal tube inclosing the cable, one end of the metal tube connecting the output of the network testing device, another end of the metal tube being earthed,
wherein both ends of a shelter and one end of a central wire contained in the cable are earthed, and an opposite end of the central wire connects the input of the network testing device, for performing cable testing.

2. A cable testing method for testing the sheltering performance of a cable, the cable having a central wire, a shelter wrapped around the central wire and an exterior cover wrapped around the shelter, the method comprising the steps of:
firstly, the cable to be tested being placed in a metal tube, one end of the metal tube being connected with an output of a network testing device, the other end of the metal tube being earthed;
secondly, one end of a central wire of the cable being earthed, meanwhile, the two ends of the shelter also being earthed, the other end of the central wire of the cable being connected with an input of the network testing device;
next, the output of the network testing device transmitting signals to change the charges on the surface of the metal tube, as a result, an electromagnetic field being formed in the interior of the metal tube;
then, the input of the network testing device receiving electromagnetic induction signals inducted by the central wire of the cable; and
lastly, the network testing device analyzing the electromagnetic induction signal inducted by the central wire placed in the metal tube, then deciding the sheltering performance of the shelter of the cable.
